(19) United States
(12) Patent Application Publication
(10) Pub. No.: US 2024/0274556 A1
(43) Pub. Date: Aug. 15, 2024

(54) SEMICONDUCTOR DEVICE AND METHOD OF FABRICATING THE SAME

(71) Applicant: Samsung Electronics Co., Ltd., Suwon-si (KR)

(72) Inventors: Won CHOI, Suwon-si (KR); Ji-Yong PARK, Suwon-si (KR); Bok Sik MYUNG, Suwon-si (KR)

(73) Assignee: Samsung Electronics Co., Ltd., Suwon-si (KR)

(21) Appl. No.: 18/481,385

(22) Filed: Oct. 5, 2023

(30) Foreign Application Priority Data
Feb. 14, 2023 (KR) 10-2023-0019662

(51) Int. Cl. H01L 23/00

(52) U.S. Cl. CPC H01L 24/05; H01L 24/08; H01L 23/3107; H01L 24/13; H01L 24/24; H01L 2224/05014; H01L 2224/05015; H01L 2224/05017; H01L 2224/08188; H01L 2224/13024; H01L 2224/24227; H01L 2924/381

(57) ABSTRACT

A semiconductor device may include a substrate, a pad on the substrate and connected to an interconnection pattern in the substrate, and a solder resist layer on the substrate, the solder resist layer having an opening exposing the pad. A top surface of the pad having a center region, and a peripheral region surrounding the center region. The center region of the top surface of the pad may be located at a level different from the peripheral region of the top surface of the pad, and a first width of the pad may be constant regardless of a distance from the substrate.

### CROSS-REFERENCE TO RELATED APPLICATIONS

This U.S. non-provisional patent application claims priority under 35 U.S.C. § 119 to Korean Patent Application No. 10-2023-0019662, filed on Feb. 14, 2023, in the Korean Intellectual Property Office, the entire contents of which are hereby incorporated by reference.

### BACKGROUND

The present disclosure relates to semiconductor devices and methods of fabricating the same, and in particular, to semiconductor devices including a bump structure and methods of fabricating the same.

In general, a semiconductor device includes an electric connection structure (e.g., solder balls or bumps), which is used for an electric connection to another semiconductor device or a printed circuit board. Thus, an electric connection structure for realizing more stable electric connection is required for the semiconductor device.

The demand for an electrode terminal structure with many pins and a small pitch is increasing rapidly in the semiconductor device. Accordingly, research on the miniaturization of semiconductor devices is increasing. The semiconductor device includes an electric connection structure (e.g., solder balls or bumps), which is used for an electric connection to another electronic device or a printed circuit board. The connection terminals of the semiconductor device are required to have high reliability.

### SUMMARY

Some example embodiments of the inventive concepts provide semiconductor devices with improved structural stability and methods of fabricating the same.

Some example embodiments of the inventive concepts provide methods of reducing a failure in a process of fabricating a semiconductor device and semiconductor devices fabricated thereby.

According to some example embodiments of the inventive concepts, a semiconductor device may include a substrate, a pad on the substrate and connected to an interconnection pattern in the substrate, and a solder resist layer on the substrate, the solder resist layer having an opening exposing the pad. A top surface of the pad having a center region, and a peripheral region surrounding the center region. The center region of the top surface of the pad may be located at a level different from the peripheral region of the top surface of the pad, and a first width of the pad may be constant regardless of a distance from the substrate.

According to some example embodiments of the inventive concepts, a semiconductor device may include a substrate having a top surface, on which a substrate pad is provided, a semiconductor chip on the substrate, the semiconductor chip having a bottom surface, on which a chip pad is provided, and a solder portion between the substrate pad and the chip pad to directly connect the chip pad to the substrate pad. A top surface of the substrate pad facing the chip pad may include a first point on a center portion of the substrate pad and a second point adjacent to an edge of the substrate pad. A difference in vertical level between the first and second points may be 10% to 50% of a thickness of the substrate pad.

According to some example embodiments of the inventive concepts, a semiconductor device may include a substrate, the substrate including a substrate pad, on a top surface of the substrate, and a solder resist layer, on the top surface of the substrate and surrounding the substrate pad, a semiconductor chip, on the substrate and having a chip pad on a bottom surface thereof, and a solder portion, between the substrate pad and the chip pad and directly connects the chip pad to the substrate pad. A top surface of the substrate pad facing the chip pad may include a curved surface and a flat surface surrounding the curved surface. The solder resist layer may be spaced apart from the substrate pad.

According to some example embodiments of the inventive concepts, a method of fabricating a semiconductor device may include forming a seed layer on a top surface of a substrate, forming a substrate pad on the top surface of the substrate, using the seed layer, forming a concave portion or a convex portion in a center region of a top surface of the substrate pad, and forming a solder resist layer, surrounding the substrate pad and spaced apart from the substrate pad, on the top surface of the substrate. A level difference between the center region and a peripheral region, surrounding the center region, may be 10% to 50% of a thickness of the substrate pad.

### BRIEF DESCRIPTION OF THE DRAWINGS

FIG. 1 is a sectional view illustrating a semiconductor device according to some example embodiments of the inventive concepts.

FIGS. 2 and 3 are enlarged sectional views illustrating a portion ‘A’ of FIG. 1.

FIGS. 4 to 6 are plan views illustrating shapes of pads.

FIG. 7 is a sectional view illustrating a semiconductor device according to some example embodiments of the inventive concepts.

FIGS. 8 to 10 are enlarged sectional views illustrating a portion ‘A’ of FIG. 1.

FIG. 11 is a sectional view illustrating a semiconductor device according to some example embodiments of the inventive concepts.

FIGS. 12 and 13 are sectional views illustrating a semiconductor package according to some example embodiments of the inventive concepts.

FIGS. 14 to 25 are diagrams illustrating a method of fabricating a semiconductor device, according to some example embodiments of the inventive concepts.

### DETAILED DESCRIPTION

Example embodiments of the inventive concepts will now be described more fully with reference to the accompanying drawings, in which example embodiments are shown.

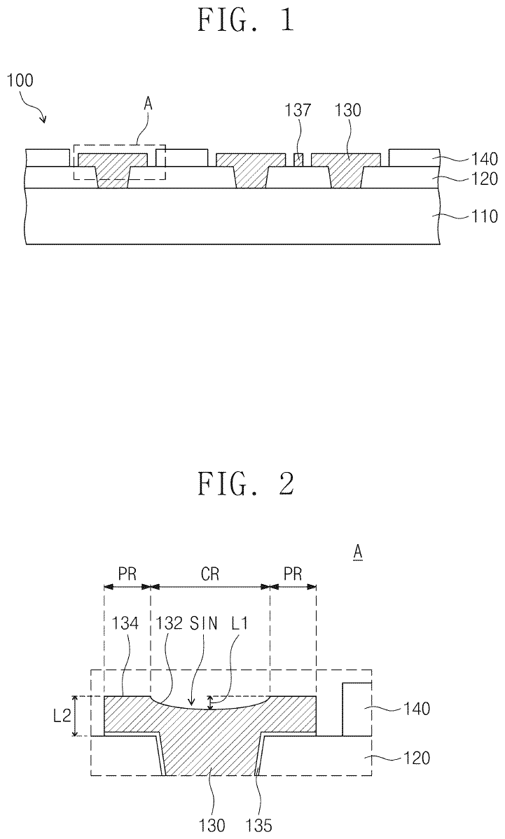

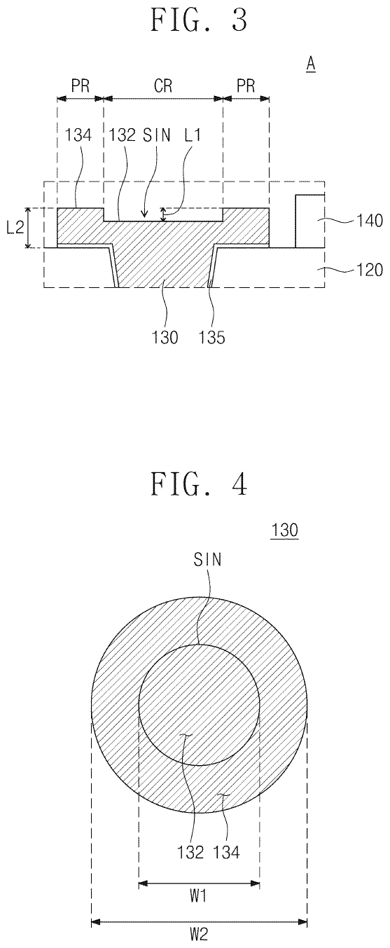

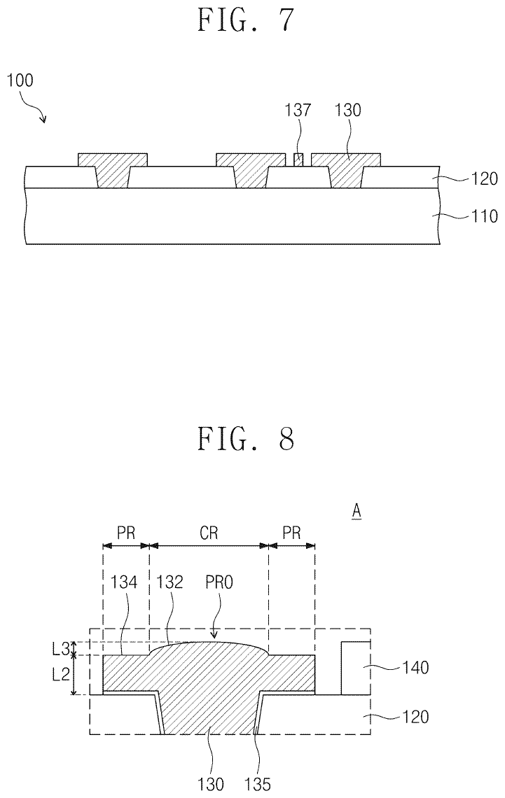

FIG. 1 is a sectional view illustrating a semiconductor device according to some example embodiments of the inventive concepts. FIGS. 2 and 3 are enlarged sectional views illustrating a portion ‘A’ of FIG. 1. FIGS. 4 to 6 are plan views illustrating shapes of pads. FIG. 7 is a sectional view illustrating a semiconductor device according to some example embodiments of the inventive concepts.

Referring to FIGS. 1 and 2, a semiconductor device may include a substrate 100. The substrate 100 may be an insulating substrate. As an example, the substrate 100 may include a printed circuit board (PCB). As another example, the substrate 100 may include a redistribution substrate. As yet another example, the substrate 100 may include a semiconductor substrate. For example, the substrate 100 may be a semiconductor substrate, such as a semiconductor wafer. The substrate 100 may be a bulk silicon wafer, a silicon-on-insulator (SOI) wafer, a germanium wafer, a germanium-on-insulator (GOI) wafer, a silicon-germanium wafer, or a substrate including an epitaxial layer formed by a selective epitaxial growth (SEG) process. For example, the substrate 100 may be formed of or include at least one of silicon (Si), germanium (Ge), silicon germanium (SiGe), gallium arsenic (GaAs), indium gallium arsenic (InGaAs), or aluminum gallium arsenic (AlGaAs).

The substrate 100 may include an interconnection layer 110, which is provided in the substrate 100. The interconnection layer 110 may include interconnection patterns and insulating patterns, which are stacked to form one or more layers. Alternatively, or additionally, the interconnection layer 110 may include a core layer, vias vertically penetrating the core layer, and peripheral portions provided on top and bottom surfaces of the core layer (not shown). The peripheral portions may include interconnection patterns, which are electrically connected to the vias.

In the case where the substrate 100 is the afore-described semiconductor substrate, the substrate 100 may include a circuit pattern provided in the substrate 100. The circuit pattern may be a memory circuit including one or more transistors, a logic circuit including one or more transistors, or combinations thereof (not shown). Alternatively, the circuit pattern may include a passive device (e.g., a resistor or a capacitor) (not shown). However, the inventive concepts are not limited to this example, and in some example embodiments, the afore-described circuit pattern may not be provided in the substrate 100.

A protection layer 120 may be provided on the interconnection layer 110. The protection layer 120 on the substrate 100 may cover the interconnection layer 110. The protection layer 120 may include an insulating material. For example, the protection layer 120 may be formed of or include photosensitive polyimide (PSPI). Alternatively, the protection layer 120 may be formed of or include at least one of silicon oxide (SiO), silicon nitride (SiN), and/or silicon oxynitride (SiON).

The substrate 100 may include at least one pad 130, which is provided on a surface of the substrate 100, and a solder resist layer 140, which including a pattern exposing the pad 130.

The pad 130 may be disposed on the protection layer 120. The pad 130 may be electrically connected to the interconnection layer 110 provided in the substrate 100. That is, the pad 130 may be used to electrically connect an interconnection circuit, which is provided in the substrate 100, to an external device or another semiconductor device. In the present specification, the expression “electrically connected or coupled” may mean that a plurality of elements are directly connected/coupled to each other or are indirectly connected or coupled to each other via another conductive element. The pad 130 may be formed of or include at least one of metallic materials. For example, the pad 130 may be formed of or include copper (Cu).

The pad 130 may have a damascene structure. For example, the pad 130 may have a head portion and a tail portion, which are connected to form a single object. The head and tail portions of the pad 130 may be provided to have a ‘T’-shaped section.

The head portion of the pad 130 may be a pad portion, which is used for connection with a connection terminal of the external device or another semiconductor device, or a wire portion, which is used for horizontal extension of an interconnection line on the protection layer 120. The head portion may be provided on a top surface of the protection layer 120. For example, the head portion may protrude above the top surface of the protection layer 120.

The tail portion of the pad 130 may be a via portion, which is used to vertically connect the pad 130 to the interconnection layer 110. The head portion may be coupled to the interconnection layer 110 through the tail portion. For example, the tail portion of the pad 130 may be extended from a bottom surface of the head portion to penetrate the protection layer 120 and may be coupled to the interconnection pattern of the interconnection layer 110. That is, there may be a transition point from the tail portion of the pad 130 to the head portion of the pad 130 at a step or large change in width.

A width of the pad 130 may be constant regardless of a distance from a top surface of the substrate 100. Here, the width of the pad 130 may be measured in a direction parallel to the top surface of the substrate 100. In some example embodiments, the width of the pad 130 may mean a width of the head portion of the pad 130, which is placed on the protection layer 120. In other words, the side surface of the pad 130 may be perpendicular to the top surface of the protection layer 120.

The pad 130 may have a center region CR and a peripheral region PR. The center region CR may be placed on a center portion of the pad 130, and the peripheral region PR may be placed on a peripheral portion of the pad 130. That is, the peripheral region PR may enclose the center region CR, when viewed in a plan view. The peripheral region PR may be located between an edge of the pad 130 and the center region CR, and in particular, between the side surface of the pad 130 and the center region CR.

A top surface of the pad 130 may have a center portion 132, which is placed on the center region CR, and a peripheral portion 134, which is placed on the peripheral region PR. The center and peripheral portions 132 and 134 may be located at different vertical levels from each other. In more detail, the center portion 132 may be located at a vertical level lower than the peripheral portion 134. Here, the vertical levels of the center and peripheral portions 132 and 134 may be measured from a bottom surface of the substrate 100 in a direction perpendicular to the top surface of the substrate 100. That is, a first point, which is an arbitrary point on the center portion 132, may be located at a level that is equal to or lower than a second point, which is an arbitrary point on the peripheral portion 134. In other words, the center portion 132 may be a recessed portion SIN of the pad 130. A difference in vertical level of the first and second points may be about or exactly 10% to about or exactly 50% of a thickness of the pad 130. A recess depth of the recessed portion SIN may range from about or exactly 3 μm to about or exactly 10 μm.

As shown in FIG. 2, the peripheral portion 134 may include a substantially flat or flat surface. The center portion 132 may include a concave surface. In more detail, the center portion 132 may have a concave surface which is recessed from the peripheral portion 134. For example, a cross-section of the recessed portion SIN, which is formed by the center portion 132, may have a semi-circular shape or a semi-elliptical shape, which is achieved by slicing an ellipse along its longitudinal axis. A vertical level difference L1 between the center and peripheral portions 132 and 134 (for example, a depth of the recessed portion SIN) may be about or exactly 10% to about or exactly 50% of a thickness L2 of the pad 130. Here, the vertical level difference L1 between the center and peripheral portions 132 and 134 may be a vertical distance from the peripheral portion 134 to the lowermost point of the center portion 132. Here, the thickness L2 of the pad 130 may mean a thickness of the head portion of the pad 130 placed on the protection layer 120 or may mean a distance from the bottom surface of the head portion to the top surface of the head portion (for example, the peripheral portion 134). The vertical level difference L1 between the center and peripheral portions 132 and 134 may range from about or exactly 3 μm to about or exactly 10 μm. In some example embodiments of FIG. 2, the center portion 132 is illustrated to have a concave surface, but the inventive concepts are not limited to this example.

FIG. 2 illustrates an example in which the center and peripheral portions 132 and 134 are connected to each other at a boundary between the center and peripheral portions 132 and 134, but the inventive concepts are not limited to this example. For example, the center and peripheral portions 132 and 134 may be vertically spaced apart from each other at the boundary of the center and peripheral portions 132 and 134. In other words, at the boundary of the center and peripheral portions 132 and 134, the center and peripheral portions 132 and 134 may be located at different vertical levels from each other to form a stepwise structure.

As shown in FIG. 3, the peripheral portion 134 may include a substantially flat or flat surface. The center portion 132 may include a substantially flat or flat surface. In more detail, the center portion 132 may have a flat surface which is stepped with the peripheral portion 134. For example, the center portion 132 may constitute a recess, which is recessed relative to the peripheral portion 134 in a direction toward an inner portion of the pad 130, and in this case, the recess may have a bottom surface, which is located at a vertical level lower than the peripheral portion 134, and an inner side surface, which connects the bottom surface to the peripheral portion 134. That is, a cross-section of the recessed portion SIN formed by the center portion 132 may have a square or rectangular shape or a trapezoidal shape. The vertical level difference L1 between the center and peripheral portions 132 and 134 may be about or exactly 10% to about or exactly 50% of the thickness L2 of the pad 130. Here, the vertical level difference L1 between the center and peripheral portions 132 and 134 may be a vertical distance between the flat surfaces of the center and peripheral portions 132 and 134. The vertical level difference L1 between the center and peripheral portions 132 and 134 may range from about or exactly 3 μm to about or exactly 10 μm.

In the semiconductor device according to some example embodiments of the inventive concepts, the pad 130 of the substrate 100 may have the recessed portion SIN, which is formed by recessing the center portion 132 of the top surface of the pad 130. Accordingly, when an external device or another semiconductor device is mounted on the pad 130, a connection terminal, such as a solder ball, may be easily aligned to the pad 130. In more detail, the external device or the semiconductor device may be placed on the substrate 100, and then, the external device or the semiconductor device may be moved toward the substrate 100 such that the connection terminal is placed adjacent to the pad 130. Here, the external device or the semiconductor device may be slid to align the connection terminal of the external or semiconductor device with the pad 130. This is because the recessed portion SIN, which is recessed (for example, concavely or stepwise) toward the inner portion of the pad 130, is formed in the pad 130. That is, the substrate 100 may be aligned to the external device or the semiconductor device in a self-aligned manner (for example, without an additional alignment component). As a result, the external device or the semiconductor device may be mounted on the substrate 100 without any misalignment issue, and the connection terminal of the external or semiconductor device may be stably bonded to the pad 130. Consequently, it may be possible to reduce or suppress a non-wet failure in a semiconductor device.

Referring back to FIGS. 1-3, the planar shape of the center portion 132 of the top surface of the pad 130 may be variously changed, if necessary.

As shown in FIG. 4, the pad 130 may have a circular shape, when viewed in a plan view. The center portion 132 may have the same or similar planar shape as that of the pad 130. For example, the center portion 132 may have a circular or elliptical shape, when viewed in a plan view. In some example embodiments of FIG. 4, the center portion 132 is illustrated to have a circular shape in a plan view, but the inventive concepts are not limited to this example.

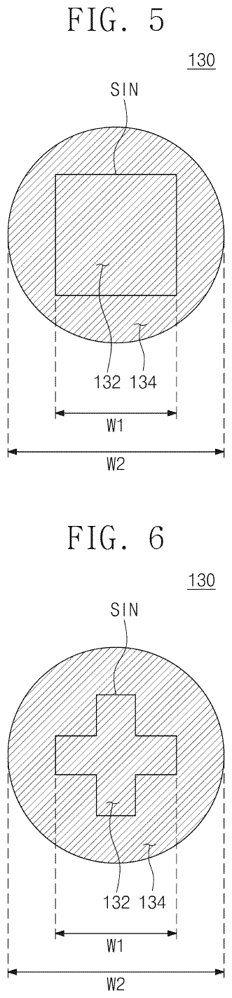

As shown in FIG. 5, the pad 130 may have a circular shape, when viewed in a plan view. The center portion 132 may have a planar shape different from that of the pad 130. For example, the center portion 132 may have a tetragonal shape, when viewed in a plan view. As an example, the planar shape of the center portion 132 may be square or rectangular.

In some example embodiments, as shown in FIG. 6, the pad 130 may have a circular shape, when viewed in a plan view. The center portion 132 may have a planar shape different from the planar shape of the pad 130. For example, the center portion 132 may have a cross or asterisk shape, when viewed in a plan view. Alternatively, the center portion 132 may have a stellate shape, when viewed in a plan view.

In the semiconductor device according to some example embodiments of the inventive concepts, the pad 130 of the substrate 100 may have the recessed portion SIN, which is formed by recessing the center portion 132 of the top surface of the pad 130. In some example embodiments, there may be corners between the center and peripheral portions 132 and 134. Thus, in a process of mounting an external device or another semiconductor device on the pad 130, the external or semiconductor device may be aligned to the substrate 100 in a self-aligned manner (e.g., without an additional alignment component) by a surface tension of a solder ball melted during a reflow step. In the case where the center portion 132 has a polygonal or asterisk shape in a plan view, the number of the corners between the center and peripheral portions 132 and 134 may be increased, and this may facilitate the self-alignment process using the surface tension of the melted solder ball.

FIGS. 4 to 6 illustrate examples, in which the pad 130 has a circular shape in a plan view, but the inventive concepts are not limited to this example. In some example embodiments, the pad 130 may have a tetragonal, polygonal, cross, or linear shape or may have an irregular shape, when viewed in a plan view.

Referring back to FIGS. 1 to 4, a first width W1 of the center portion 132 may be smaller than a second width W2 of the pad 130. For example, the first width W1 of the center portion 132 may be about or exactly 30% to about or exactly 70% of the second width W2 of the pad 130. Here, the first width W1 and the second width W2 may be measured in a direction parallel to the top surface of the substrate 100. Here, the first width W1 may be the largest width of the center portion 132, and the second width W2 may be the largest width of the pad 130. As an example, in the case where the center portion 132 has a circular shape as shown in the plan view of FIG. 4, the first width W1 may correspond to a diameter of the circle. As an example, in the case where the center portion 132 has a square shape as shown in the plan view of FIG. 5, the first width W1 may correspond to a length of one side of the square. As an example, in the case where the center portion 132 has a cross shape as shown in the plan view of FIG. 6, the first width W1 may correspond to a length of a longer one of two intersecting axes of the cross. The first width W1 of the center portion 132 may range from about or exactly 30 μm to about or exactly 50 μm.

So far, the structure of the pad 130 has been described based on one pad 130, but the inventive concepts are not limited to this example. For example, if necessary, a plurality of pads 130 may be provided. In this case, on the protection layer 120, the pads 130 may be spaced apart from each other. A distance between the pads 130 may be larger than 20 μm.

The pad 130 may further include a seed layer 135. The seed layer 135 may cover (for example, conformally cover) a bottom surface of the pad 130. For example, the seed layer 135 may cover the bottom surfaces of the head and tail portions of the pad 130 and the side surface of the tail portion of the pad 130. The seed layer 135 may be interposed between the pad 130 and the protection layer 120. In some example embodiments, the seed layer 135 may cover the bottom or side surface of the pad 130. The seed layer 135 may be formed of or include at least one of metallic materials (e.g., gold (Au) and/or silver (Ag)).

An interconnection pattern 137 may be provided between the pads 130. The interconnection pattern 137 may be disposed between two adjacent ones of the pads 130. The interconnection pattern 137 may be horizontally spaced apart from the pads 130. The interconnection pattern 137 may be an interconnection line, which is connected to the pads 130, or a seed line, which is used for a plating process of forming the pads 130. The interconnection pattern 137 may be formed of or include at least one of metallic materials. For example, the pad 130 may be formed of or include copper (Cu). In some example embodiments, the interconnection pattern 137 may not be provided.

The solder resist layer 140 may be disposed on the protection layer 120. When viewed in a plan view, the solder resist layer 140 may enclose the pad 130. Here, the solder resist layer 140 may be horizontally spaced apart from the pad 130. In more detail, the solder resist layer 140 may have an opening, which is formed to vertically penetrate the solder resist layer 140. The pad 130 may be provided in the opening of the solder resist layer 140 and may be spaced apart from an inner side surface of the opening. In the case where a plurality of pads 130 are provided, one pad 130 or two or more pads 130 may be disposed in each opening. A top surface of the solder resist layer 140 may be located at a level higher than the top surface of the pad 130. The interconnection pattern 137 may be provided in the opening of the solder resist layer 140 or may be buried in the solder resist layer 140. The solder resist layer 140 may be formed of or include a solder resist material. In some example embodiments, the solder resist layer 140 may extend higher (for example, be taller) than the pad 130, that is, may have a height (or thickness) greater than the thickness L2.

In some example embodiments, the solder resist layer 140 may cover at least a portion of the pad 130.

In some example embodiments, the solder resist layer may not be provided, as shown in FIG. 7. For example, the pad 130 and the interconnection pattern 137 may be placed on the protection layer 120 but may not be covered or veiled with any other element.

In the description of the example embodiments to be explained below, an element previously described with reference to FIGS. 1 to 7 may be identified by the same reference number without repeating an overlapping description thereof, for concise description.

FIGS. 8 to 10 are enlarged sectional views illustrating a portion ‘A’ of FIG. 1.

Some example embodiments of FIGS. 2 and 3 illustrates an example in which the center portion 132 of the pad 130 is located at a vertical level lower than the peripheral portion 134, but the inventive concepts are not limited to this example.

Referring to FIGS. 1 and 8, the top surface of the pad 130 may have the center portion 132, which is placed on the center region CR, and the peripheral portion 134, which is placed on the peripheral region PR. The center and peripheral portions 132 and 134 may be located at different vertical levels from each other. In more detail, the center portion 132 may be located at a vertical level higher than the peripheral portion 134. That is, a first point, which is an arbitrary point on the center portion 132, may be located at a level that is equal to or higher than a second point, which is an arbitrary point on the peripheral portion 134. In other words, the center portion 132 may be a protruding portion PRO of the pad 130. A protruding height of the protruding portion PRO may range from about or exactly 3 μm to about or exactly 10 μm.

As shown in FIG. 8, the peripheral portion 134 may include a substantially flat or flat surface. The center portion 132 may include a convex surface. In more detail, the center portion 132 may have a convex surface, which protrudes above the peripheral portion 134. For example, a cross-section of the protruding portion PRO, which is formed by the center portion 132, may have a semi-circular shape or a semi-elliptical shape, which is achieved by slicing an ellipse along its longitudinal axis. A vertical level difference L3 of the center and peripheral portions 132 and 134 (for example, a height of the protruding portion PRO) may be about or exactly 10% to about or exactly 50% of the thickness L2 of the pad 130. Here, the vertical level difference L3 between the center and peripheral portions 132 and 134 may be a vertical distance from the peripheral portion 134 to the uppermost point of the center portion 132. The vertical level difference L3 between the center and peripheral portions 132 and 134 may range from about or exactly 3 μm to about or exactly 10 μm.

FIG. 8 illustrates an example in which the center and peripheral portions 132 and 134 are connected to each other at the boundary between the center and peripheral portions 132 and 134, but the inventive concepts are not limited to this example. For example, the center and peripheral portions 132 and 134 may be vertically spaced apart from each other at the boundary of the center and peripheral portions 132 and 134. In other words, at the boundary of the center and peripheral portions 132 and 134, the center and peripheral portions 132 and 134 may be located at different vertical levels from each other to form a stepwise structure.

Some example embodiments of FIG. 8 illustrates an example in which the center portion 132 has a convex surface, but the inventive concepts are not limited to this example.

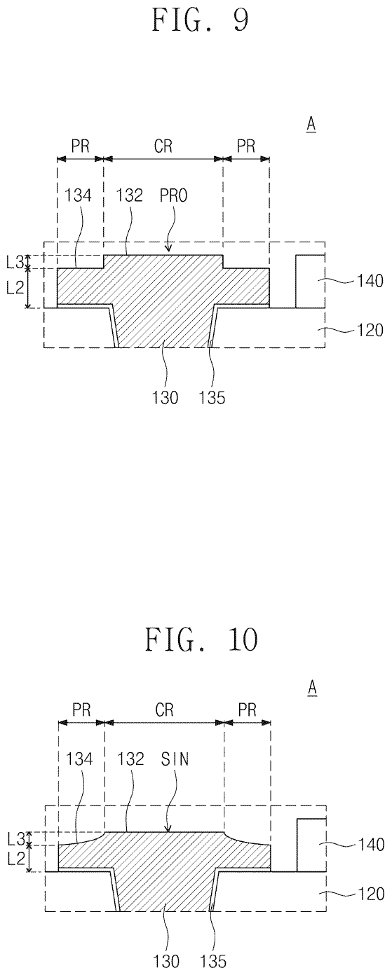

As shown in FIG. 9, the peripheral portion 134 may include a substantially flat or flat surface. The center portion 132 may include a substantially flat or flat surface. In more detail, the center portion 132 may have a flat surface which is stepped with the peripheral portion 134. For example, the center portion 132 may constitute the protruding portion PRO, which protrudes upward from the peripheral portion 134, and the protruding portion PRO may have a top surface, which is located at a vertical level higher than the peripheral portion 134, and an outer side surface, which connects the top surface to the peripheral portion 134. That is, a cross-section of the protruding portion PRO formed by the center portion 132 may have a square or rectangular shape or a trapezoidal shape. The vertical level difference L3 between the center and peripheral portions 132 and 134 may be about or exactly 10% to about or exactly 50% of the thickness L2 of the pad 130. Here, the vertical level difference L3 between the center and peripheral portions 132 and 134 may be a vertical distance between the flat surfaces of the center and peripheral portions 132 and 134. The vertical level difference L3 between the center and peripheral portions 132 and 134 may range from about or exactly 3 μm to about or exactly 10 μm.

Alternatively, as shown in FIG. 10, the center portion 132 may include a substantially flat or flat surface. The peripheral portion 134 may include a concave surface. In more detail, the peripheral portion 134 may have a concave surface, which is recessed from the center portion 132. The vertical level difference L3 between the center and peripheral portions 132 and 134 may be about or exactly 10% to about or exactly 50% of the thickness L2 of the pad 130. Here, the vertical level difference L3 between the center and peripheral portions 132 and 134 may be a vertical distance from the center portion 132 to the lowermost point of the peripheral portion 134. The vertical level difference L1 between the center and peripheral portions 132 and 134 may range from about or exactly 3 μm to about or exactly 10 μm.

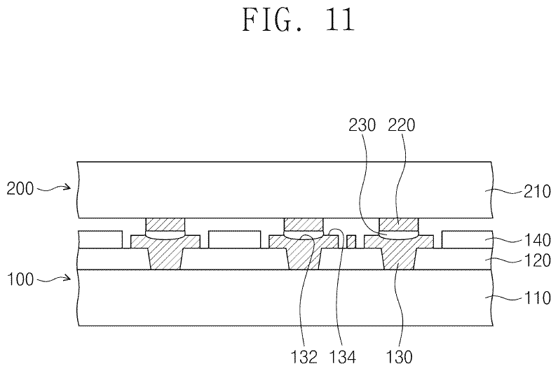

FIG. 11 is a sectional view illustrating a semiconductor device according to some example embodiments of the inventive concepts.

Referring to FIG. 11, the substrate 100 may be provided. The substrate 100 may have the same structure as the substrate 100 described with reference to FIGS. 1 to 10. For example, the substrate 100 may include the interconnection layer 110, the protection layer 120 on the interconnection layer 110, the pad 130, which is provided on the protection layer 120 to penetrate the protection layer 120 and is connected to the interconnection layer 110, and the solder resist layer 140, which is provided on the protection layer 120 to enclose the pad 130. The pad 130 may include a recessed portion, in which the center portion 132 is lower than the peripheral portion 134, or a protruding portion, in which the center portion 132 is higher than the peripheral portion 134.

An electronic device 200 may be disposed on the substrate 100. For example, the electronic device 200 may include a semiconductor chip, a passive device chip, an outer input-output unit, a motherboard, or the like. The electronic device 200 may include a device substrate 210 and a bump structure provided on the device substrate 210.

The device substrate 210 may include a semiconductor substrate. For example, the device substrate 210 may be a semiconductor substrate, such as a semiconductor wafer. The device substrate 210 may be a bulk silicon wafer, a silicon-on-insulator (SOI) wafer, a germanium wafer, a germanium-on-insulator (GOI) wafer, a silicon-germanium wafer, or a substrate including an epitaxial layer formed by a selective epitaxial growth (SEG) process. The device substrate 210 may be formed of or include at least one of silicon (Si), germanium (Ge), silicon germanium (SiGe), gallium arsenic (GaAs), indium gallium arsenic (InGaAs), or aluminum gallium arsenic (AlGaAs). The device substrate 210 may include a circuit pattern and a protection layer. The circuit pattern may include one or more transistors, which are used to constitute a memory circuit, a logic circuit, a passive device, a connector, or combinations thereof. Alternatively, the circuit pattern may include passive devices, such as a resistor and/or a capacitor.

A bump structure may be disposed on the device substrate 210. The bump structure may include a metal layer 220 and a solder ball 230.

The metal layer 220 may be disposed on the device substrate 210. The metal layer 220 may be electrically connected to the circuit pattern of the device substrate 210. The metal layer 220 may have a tetragonal shape, when viewed in a plan view. Alternatively, the metal layer 220 may have a circular shape, when viewed in a plan view. However, the inventive concepts are not limited to these examples, and the planar shape of the metal layer 220 may be variously changed, if necessary. Side surfaces of the metal layer 220 may be perpendicular to the bottom surface of the device substrate 210. For example, the side surfaces of the metal layer 220 may be parallel to each other. A width of the metal layer 220 may be constant, regardless of a distance from the bottom surface of the device substrate 210. The metal layer 220 may be formed of or include at least one of metallic materials. For example, the metal layer 220 may be formed of or include copper (Cu) or nickel (Ni). Although not shown, a seed layer may be provided on the metal layer 220. In some example embodiments, the seed layer may be formed of or include gold (Au) or the like.

The solder ball 230 may be disposed on the metal layer 220. The solder ball 230 may be spaced apart from the device substrate 210 by the metal layer 220. A width of the solder ball 230 may be larger than a width of the metal layer 220. The solder ball 230 may be formed of or include a soldering material for a bonding process. For example, the solder ball 230 may be formed of or include at least one of tin (Sn), silver (Ag), copper (Cu), zinc (Zn), lead (Pb), and/or alloys thereof.

The electronic device 200 may be mounted on the substrate 100. For example, the bump structure of the electronic device 200 may be placed on and aligned to the pad 130 of the substrate 100. The solder ball 230 of the bump structure may be in contact with the pad 130. The solder ball 230 may be in contact with the entirety of the center portion 132 of the top surface of the pad 130. In more detail, the solder ball 230 may be provided to fill a recessed portion formed in the center portion 132. Alternatively, in the case where the center portion 132 is provided as a protruding portion of the pad 130, the solder ball 230 may enclose the protruding portion formed in the center portion 132.

According to some example embodiments of the inventive concepts, an adhesion area between the solder ball 230 of the electronic device 200 and the pad 130 of the substrate 100 may be increased, and in this case, a bonding strength between the solder ball 230 and the pad 130 may be increased. That is, it may be possible to improve the structural stability of the semiconductor device.

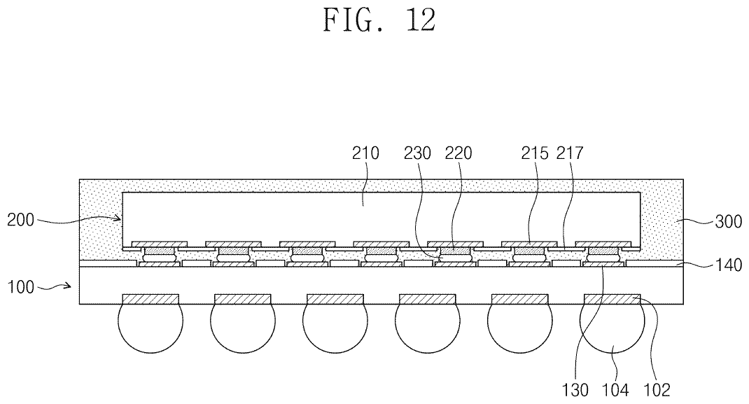

FIG. 12 is a sectional view illustrating a semiconductor package according to some example embodiments of the inventive concepts.

Referring to FIG. 12, the substrate 100 may be provided. The substrate 100 may be the same as or similar to the substrate 100 described with reference to FIGS. 1 to 10. For example, the substrate 100 may include the pad 130 and the solder resist layer 140, which are provided near the top surface of the substrate 100, and an outer pad 102, which is provided near the bottom surface of the substrate 100. The pad 130 may be connected to an interconnection pattern in the substrate 100. The solder resist layer 140 may be provided to enclose the pad 130. The pad 130 may have a recessed portion, in which the center portion of the top surface thereof is recessed relative to the peripheral portion, or a protruding portion, in which the center portion protrudes relative to the peripheral portion.

The outer pad 102 may be electrically connected to the interconnection pattern of the substrate 100. The outer pad 102 may be used as a pad, which is coupled with an outer terminal 104.

The outer terminal 104 may be provided on a bottom surface of the outer pad 102. The outer terminal 104 may include a solder ball or a solder bump, and depending on the kind and arrangement of the outer terminals 104, the semiconductor package may have a ball-grid array (BGA) structure, a fine ball-grid array (FBGA) structure, or a land grid array (LGA) structure.

A semiconductor chip 200 may be provided on the substrate 100. The semiconductor chip 200 may be an example of the electronic device 200 described with reference to FIG. 11. The semiconductor chip 200 may include a semiconductor substrate 210, a chip pad 215, a chip protection layer 217, and a solder structure.

The semiconductor substrate 210 may be provided. The semiconductor substrate 210 may be formed of or include a semiconductor material. For example, the semiconductor substrate 210 may be a single-crystalline silicon substrate. The semiconductor substrate 210 may include a circuit pattern and a protection layer. The circuit pattern may include one or more transistors, which are used to constitute a memory circuit, a logic circuit, a passive device, a connector, or combinations thereof. Alternatively, the circuit pattern may include passive devices, such as a resistor and/or a capacitor.

The chip pad 215 may be disposed on the semiconductor substrate 210. The chip pad 215 may be disposed on an active surface of the semiconductor substrate 210 and may be electrically connected to the circuit pattern.

That is, the chip pad 215 may be used to connect a memory circuit, a logic circuit, or combinations thereof, which are formed in the semiconductor substrate 210, to an external device or another semiconductor device. Alternatively, the chip pad 215 may be used as a pad, which is connected to an interconnection pattern provided on the semiconductor substrate 210. The chip pad 215 may be formed of or include at least one of metallic materials. For example, the chip pad 215 may be formed of or include aluminum (Al).

The chip protection layer 217 may be provided on the semiconductor substrate 210 to cover the chip pad 215. The chip protection layer 217 may be formed of or include an insulating material. For example, the chip protection layer 217 may be formed of or include photosensitive polyimide (PSPI). Alternatively, the chip protection layer 217 may be formed of or include at least one of silicon oxide (SiO), silicon nitride (SiN), and/or silicon oxynitride (SiON). The chip protection layer 217 may have an opening, which is formed to vertically penetrate the chip protection layer 217. The opening may expose at least a portion of a bottom surface of the chip pad 215. When viewed in a plan view, the chip pad 215 may be placed in the opening.

The bump structure may be provided on the chip pad 215. In more detail, the bump structure may be located within the opening of the chip protection layer 217. The bump structure may be coupled to the bottom surface of the chip pad 215 exposed by the opening. In the opening, the bump structure may be spaced apart from the chip protection layer 217.

The bump structure may include the metal layer 220 and the solder ball 230. The metal layer 220 and the solder ball 230 may be sequentially stacked on the chip pad 215. In other words, the metal layer 220 may be disposed on the chip pad 215, and the solder ball 230 may be disposed on the metal layer 220.

The metal layer 220 may be electrically connected to the chip pad 215. The metal layer 220 may have a tetragonal or circular shape, when viewed in a plan view. Side surfaces of the metal layer 220 may be perpendicular to the bottom surface of the chip pad 215. For example, the side surfaces of the metal layer 220 may be parallel to each other. A width of the metal layer 220 may be constant, regardless of a distance from the bottom surface of the chip pad 215. The metal layer 220 may include a metallic material. For example, the metal layer 220 may be formed of or include copper (Cu) or nickel (Ni).

The solder ball 230 may be disposed on the metal layer 220. The solder ball 230 may be spaced apart from the chip pad 215 by the metal layer 220. A width of the solder ball 230 may be larger than a width of the metal layer 220. The solder ball 230 may be formed of or include a soldering material for a bonding process. For example, the solder ball 230 may be formed of or include at least one of tin (Sn), silver (Ag), copper (Cu), zinc (Zn), lead (Pb), and/or alloys thereof.

The semiconductor chip 200 may be mounted on the substrate 100. For example, the bump structure of the semiconductor chip 200 may be aligned to the pad 130 of the substrate 100. The solder ball 230 of the bump structure may be in contact with the pad 130. The solder ball 230 may be bonded to the entirety of the center portion 132 of the top surface of the pad 130. In more detail, the solder ball 230 may be provided to fill a recessed portion formed in the center portion 132. Alternatively, in the case where the center portion 132 is provided as the protruding portion of the pad 130, the solder ball 230 may enclose the protruding portion formed in the center portion 132.

A mold layer 300 may be provided on the top surface of the substrate 100 to cover the semiconductor chip 200. In some example embodiments, the mold layer 300 may be formed of or include an epoxy molding compound (EMC). In some example embodiments, an underfill layer (not shown) may be further provided between the semiconductor chip 200 and the substrate 100.

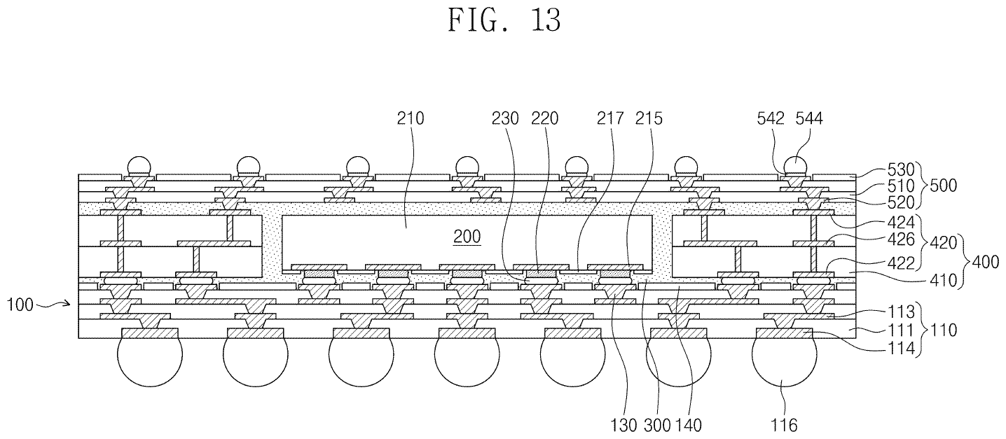

FIG. 13 is a sectional view illustrating a semiconductor package according to some example embodiments of the inventive concepts.

Referring to FIG. 13, a package substrate 100 may be provided. The substrate 100 may be the same as or similar to the substrate 100 described with reference to FIGS. 1 to 10. For example, the package substrate 100 may include a plurality of interconnection layers 110.

The interconnection layers 110 may include insulating patterns 111, which are sequentially stacked on top of each other, substrate pads 130, which are provided on a top surface of the package substrate 100, outer pads 114, which are provided on a bottom surface of the package substrate 100, and conductive patterns 113, which are provided in the insulating patterns 111 to connect the substrate pads 130 to the outer pads 114. Furthermore, outer terminals 116 may be provided on the outer pads 114. In some example embodiments, the substrate pads 130 may be portions of the conductive patterns 113, which are exposed to the outside of the package substrate 100 near the top surface of the package substrate 100. Alternatively, the package substrate 100 may have additional substrate pads 130, which are disposed on the top surface of the package substrate 100 and are connected to the conductive patterns 113. The solder resist layer 140 may be disposed on the top surface of the package substrate 100. The solder resist layer 140 may enclose the substrate pads 130. The substrate pad 130 may have a recessed portion, in which the center portion of the top surface thereof is recessed relative to the peripheral portion, or a protruding portion, in which the center portion protrudes relative to the peripheral portion.

A connection substrate 400 may be disposed on the package substrate 100. The connection substrate 400 may have a mounting region, which is provided in the form of a hole. For example, the mounting region may be provided in the form of an open hole connecting top and bottom surfaces of the connection substrate 400. The bottom surface of the connection substrate 400 may be spaced apart from the top surface of the package substrate 100. The connection substrate 400 may include a base layer 410 and a conductive portion 420, which is an interconnection pattern provided in the base layer 410. In some example embodiments, the base layer 410 may be formed of or include silicon oxide. The conductive portion 420 may be disposed in an outer region of the connection substrate 400 outside the mounting region. The conductive portion 420 may include lower pads 422, upper pads 424, and vias 426. The lower pads 422 may be disposed in a lower portion of the connection substrate 400. The upper pads 424 may be disposed on the top surface of the connection substrate 400. The vias 426 may be provided to penetrate the base layer 410 and may electrically connect the lower pads 422 to the upper pads 424.

The connection substrate 400 may be mounted on the package substrate 100. For example, the bottom surface of the connection substrate 400 may be in connect with the top surface of the package substrate 100. Here, the lower pads 422 of the connection substrate 400 may face the substrate pads 130 of the package substrate 100. In other words, some of the substrate pads 130 of the package substrate 100 may be vertically aligned to the lower pads 422 of the connection substrate 400. The connection substrate 400 may be connected to the substrate pads 130 of the package substrate 100 through connection terminals, which are provided on the lower pads 422. Accordingly, the connection substrate 400 may be electrically connected to the semiconductor chip 200 and outer terminals 116.

The semiconductor chip 200 may be substantially the same as the semiconductor chip 200 described with reference to FIG. 12. In some example embodiments, the semiconductor chip 200 may include the semiconductor substrate 210, the chip pads 215, the chip protection layer 217, and the solder structures.

The bump structures may be provided on the chip pad 215. In more detail, the bump structures may be respectively placed inside the openings of the chip protection layer 217. The bump structures may be coupled to the bottom surfaces of the chip pads 215 exposed by the openings. In the openings, the bump structures may be spaced apart from the chip protection layer 217. Each of the bump structures may include the metal layer 220 and the solder ball 230. The metal layer 220 and the solder ball 230 may be sequentially stacked on one of the chip pads 215. In other words, the metal layer 220 may be disposed on the chip pad 215, and the solder ball 230 may be disposed on the metal layer 220.

The semiconductor chip 200 may be mounted on the package substrate 100. For example, the semiconductor chip 200 may be disposed in the mounting region of the connection substrate 400. The semiconductor chip 200 may be provided such that the bump structures of the semiconductor chip 200 face the top surface of the package substrate 100. The bump structures of the semiconductor chip 200 may be aligned to the substrate pads 130 of the package substrate 100. The solder ball 230 of the bump structures may be in contact with the pad 130. Each of the solder balls 230 may be in contact with the entirety of the center portion 132 of a top surface of a corresponding one of the pads 130. In more detail, each of the solder balls 230 may be provided to fill a recessed portion, which is formed in the center portion 132. Alternatively, in the case where the center portions 132 of the pads 130 are provided as protruding portions, the solder balls 230 may be provided to enclose the center portions 132 or the protruding portions.

The mold layer 300 may cover the connection substrate 400 and the semiconductor chip 200. The mold layer 300 may be provided to fill a space between the semiconductor chip 200 and the connection substrate 400, a space between the semiconductor chip 200 and the package substrate 100, and a space between the connection substrate 400 and the package substrate 100. In some example embodiments, the mold layer 300 may be formed of or include an epoxy molding compound (EMC). In some example embodiments, an underfill layer (not shown) may be further provided between the semiconductor chip 200 and the package substrate 100 or between the connection substrate 400 and the package substrate 100.

A redistribution layer 500 may be provided on the mold layer 300. The redistribution layer 500 may cover the semiconductor chip 200 and the connection substrate 400. The redistribution layer 500 may be in contact with a top surface of the mold layer 300. The redistribution layer 500 may include insulating patterns 510, which are sequentially stacked, and conductive patterns 520, which are provided in the insulating patterns 510. Portions of the conductive patterns 520 may be provided to penetrate insulating patterns 510 and the mold layer 300 and may be connected to the upper pads 424 of the connection substrate 400. The portions of the conductive patterns 520 may be pads of the redistribution layer 500, which are exposed to the outside of the redistribution layer 500 near a top surface of the redistribution layer 500. The redistribution layer 500 may further include a protection layer 530 covering the top surface of the redistribution layer 500. The protection layer 530 may have openings exposing the pads of the redistribution layer 500.

The bump structures may be disposed on the pads of the redistribution layer 500, respectively. Each of the bump structures may include a metal layer 542 and a solder ball 544. The metal layer 542 and the solder ball 544 may be sequentially stacked on one of the pads of the redistribution layer 500. That is, the metal layer 542 may be disposed on the pads of the redistribution layer 500, and the solder ball 544 may be disposed on the metal layer 542.

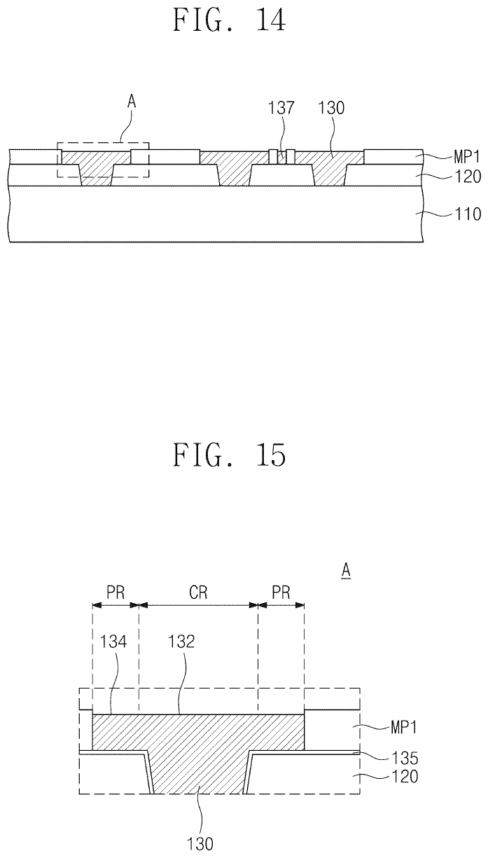

FIGS. 14 to 25 are diagrams illustrating a method of fabricating a semiconductor device, according to some example embodiments of the inventive concepts. FIGS. 14, 16, and 18 are sectional views illustrating a semiconductor device, and FIGS. 15, 17, and 19 are enlarged sectional views illustrating portions ‘A’ of FIGS. 14, 16, and 18.

Referring to FIGS. 14 and 15, the substrate 100 may be provided. The substrate 100 may be an insulating substrate. For example, the substrate 100 may include a printed circuit board (PCB) or a redistribution substrate. The substrate 100 may include the interconnection layer 110 provided therein. The interconnection layer 110 may include interconnection patterns, which are provided in the interconnection layer 110.

Alternatively, the substrate 100 may include a semiconductor substrate. For example, the substrate 100 may be a semiconductor substrate (e.g., a semiconductor wafer). A memory circuit, a logic circuit, or combinations thereof may be formed on the substrate 100.

The protection layer 120 may be formed on the substrate 100. The protection layer 120 may cover the interconnection layer 110. For example, the formation of the protection layer 120 may include coating or depositing a photosensitive material on the interconnection layer 110 and performing exposure and developing steps on the photosensitive material. The protection layer 120 may have an opening, which is formed to expose an interconnection pattern of the interconnection layer 110.

The seed layer 135 may be formed on the protection layer 120. For example, the seed layer 135 may be formed by depositing a metal layer to conformally cover the top surface of the protection layer 120 and an inner side surface and a bottom surface of the opening of the protection layer 120. The metal layer may be formed of or include at least one of metallic materials (e.g., gold (Au) or silver (Ag)). In the opening, the seed layer 135 may be coupled to the interconnection pattern of the interconnection layer 110.

A first mask pattern MP1 may be formed on the seed layer 135. The first mask pattern MP1 may have a pattern hole, which is formed to vertically penetrate the first mask pattern MP1 and expose the seed layer 135. The pattern hole may define a region, on which the pad 130 will be formed in a subsequent step. The pattern hole may be located on the opening of the protection layer 120.

The pad 130 may be formed on the seed layer 135. For example, a plating process may be performed using the seed layer 135, which is exposed by the pattern hole of the first mask pattern MP1, as a seed layer. The plating process may be performed until the top surface of the pad 130 is located at a specific height in the pattern hole. Alternatively, the plating process may be performed to form the pad 130 covering a top surface of the first mask pattern MP1, and then, a planarization or thinning process may be performed on a top surface of the pad 130. As a result, the pad 130 may have a substantially flat or flat top surface. The top surface of the pad 130 may have the center portion 132, which is placed on the center region CR, and the peripheral portion 134, which is placed on the peripheral region PR. The center portion 132 and the peripheral portion 134 may be located at the same vertical level. In more detail, the center portion 132 and the peripheral portion 134 may be coplanar with each other.

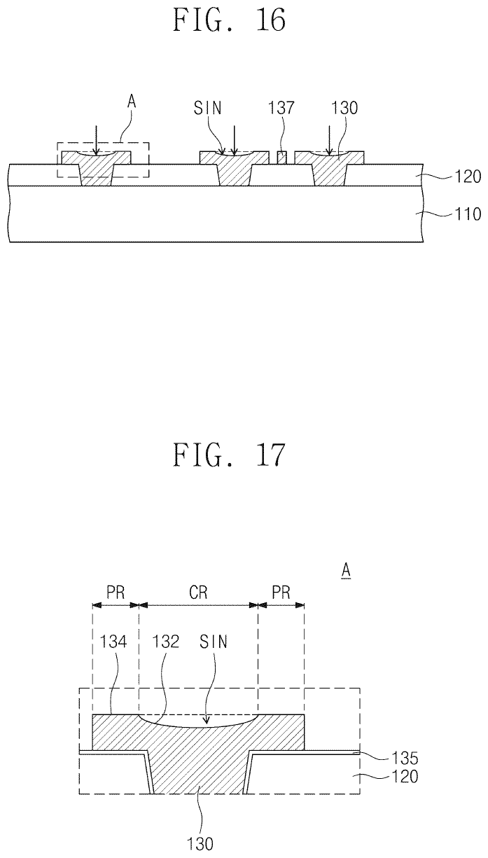

Referring to FIGS. 16 and 17, the first mask pattern MP1 may be removed. As a result of the removal of the first mask pattern MP1, the top surface of the seed layer 135 under the first mask pattern MP1 may be exposed to the outside.

A concave portion may be formed in the center portion 132 of the top surface of the pad 130. For example, a laser drilling process may be performed on the top surface of the pad 130. The laser drilling process may be performed on the center portion 132 of the top surface of the pad 130. As a result of the laser drilling process, the center portion 132 may be located at a vertical level lower than that of the peripheral portion 134. In other words, the recessed portion SIN of the pad 130 may be formed in the center portion 132. A bottom surface of the recessed portion SIN may be a concave surface, as shown in FIG. 17. Alternatively, the bottom surface of the recessed portion SIN may be a flat surface, which is located at a level lower than the peripheral portion 134. In this case, the portion ‘A’ of the semiconductor device may be fabricated to have the structure of FIG. 3. A depth of the recessed portion SIN may be about or exactly 10% to about or exactly 50% of the thickness of the pad 130.

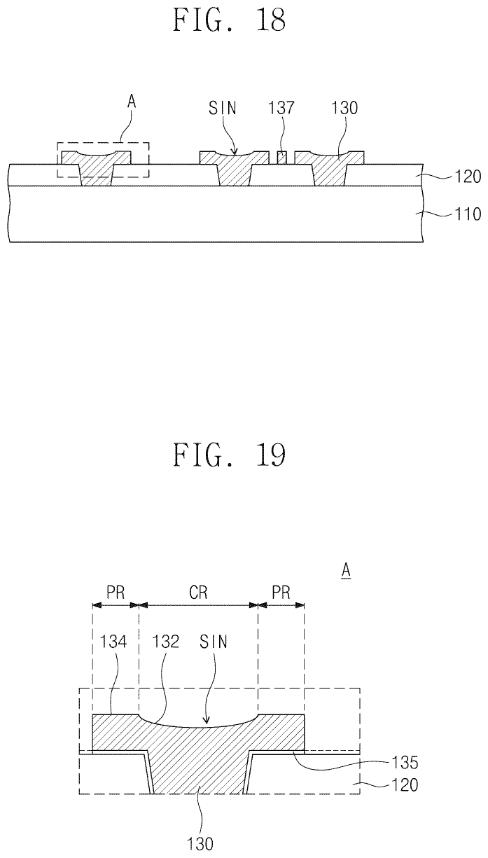

Referring to FIGS. 18 and 19, the seed layer 135 may be patterned. For example, an etching process using the pad 130 as an etch mask may be performed on a portion of the seed layer 135 exposed at a side of the pad 130. As a result of the etching process, the seed layer 135 may be left between the pad 130 and the protection layer 120.

Thereafter, referring to FIGS. 1 and 2, the solder resist layer 140 may be formed on the protection layer 120. The solder resist layer 140 may be provided to enclose the pad 130. The solder resist layer 140 may be horizontally spaced apart from the pad 130.

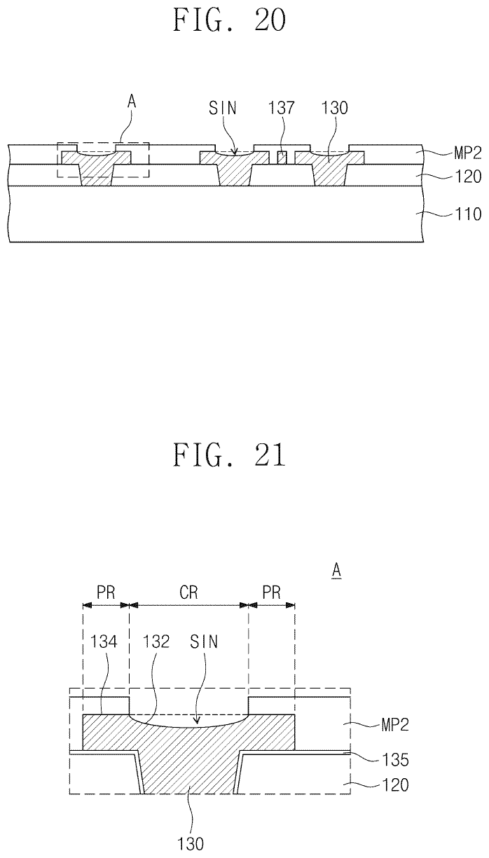

FIGS. 20 and 21 are diagrams illustrating a method of fabricating a semiconductor device, according to some example embodiments of the inventive concepts. FIG. 20 is a sectional view illustrating the semiconductor device, and FIG. 21 is an enlarged sectional view illustrating a portion ‘A’ of FIG. 20.

Referring to FIGS. 20 and 21, a second mask pattern MP2 may be formed on the resulting structure of FIGS. 18 and 19. The second mask pattern MP2 may have a pattern hole, which is formed to vertically penetrate the second mask pattern MP2 and expose the pad 130. The pattern hole may define a region, on which the recessed portion SIN will be formed in a subsequent step. The pattern hole may be located on the opening of the protection layer 120. In other words, the second mask pattern MP2 may be formed to expose the center portion 132 of the pad 130 and cover the peripheral portion 134. The pattern hole may have a circular, tetragonal, polygonal, cross, asterisk, or stellate shape, when viewed in a plan view.

A concave portion may be formed in the center portion 132 of the top surface of the pad 130. For example, an etching process may be performed using the second mask pattern MP2 as an etch mask. As a result of the etching process, the center portion 132 of the pad 130 may be etched. During the etching process, the peripheral portion 134 of the pad 130 may not be etched by the second mask pattern MP2. As a result of the etching process, the center portion 132 may be formed at a vertical level lower than that of the peripheral portion 134. In other words, the recessed portion SIN of the pad 130 may be formed in the center portion 132. A depth of the recessed portion SIN may be about or exactly 10% to about or exactly 50% of the thickness of the pad 130.

The second mask pattern MP2 may be removed. As a result of the removal of the second mask pattern MP2, the top surface of the seed layer 135 under the second mask pattern MP2 may be exposed to the outside.

The process described with reference to FIGS. 18 and 19 may be performed. For example, the seed layer 135 may be patterned. For example, an etching process using the pad 130 as an etch mask may be performed on a portion of the seed layer 135 exposed at a side of the pad 130. As a result of the etching process, the seed layer 135 may be left between the pad 130 and the protection layer 120.

Thereafter, referring to FIGS. 1 and 2, the solder resist layer 140 may be formed on the protection layer 120. The solder resist layer 140 may be provided to enclose the pad 130. The solder resist layer 140 may be horizontally spaced apart from the pad 130.

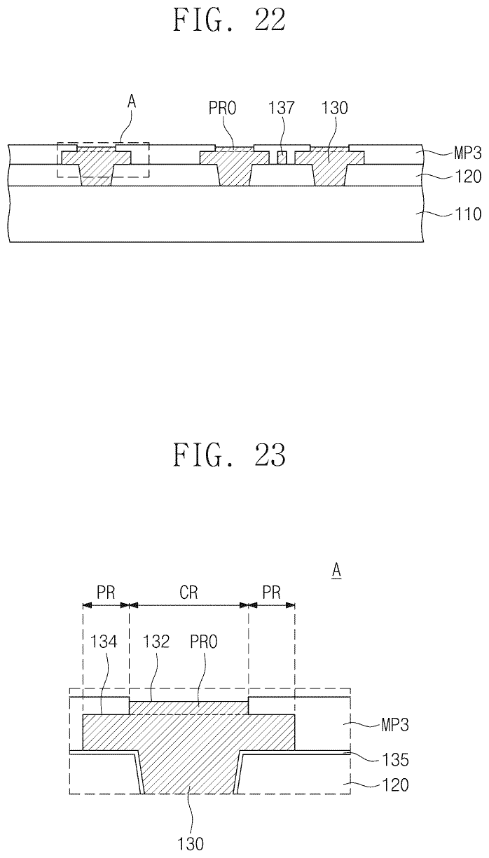

FIGS. 22 and 23 are diagrams illustrating a method of fabricating a semiconductor device, according to some example embodiments of the inventive concepts. FIG. 22 is a sectional view illustrating the semiconductor device, and FIG. 23 is an enlarged sectional view illustrating a portion ‘A’ of FIG. 22.

Referring to FIGS. 22 and 23, a third mask pattern MP3 may be formed on the resulting structure of FIGS. 18 and 19. The third mask pattern MP3 may have a pattern hole, which is formed to vertically penetrate the third mask pattern MP3 and expose the pad 130. The pattern hole may define a region, on which the protruding portion PRO will be formed in a subsequent step. The pattern hole may be located on the opening of the protection layer 120. In other words, the third mask pattern MP3 may be formed to expose the center portion 132 of the pad 130 and cover the peripheral portion 134 of the pad 130. The pattern hole may have a circular, tetragonal, polygonal, cross, asterisk, or stellate shape, when viewed in a plan view.

The protruding portion PRO may be formed on the pad 130. For example, a plating process may be performed using the center portion 132 of the top surface of the pad 130, which is exposed by the pattern hole of the third mask pattern MP3, as a seed layer. The plating process may be performed until the top surface of the protruding portion PRO is located at a specific height in the pattern hole. Alternately, the plating process may be performed to form the protruding portion PRO covering a top surface of the third mask pattern MP3, and then, a planarization or thinning process may be performed on the top surface of the protruding portion PRO. As a result of the plating process, the center portion 132 may be formed at a vertical level higher than that of the peripheral portion 134. That is, the protruding portion PRO of the pad 130 may be formed in the center portion 132. The top surface of the protruding portion PRO may be a flat surface, which is located at a level higher than the peripheral portion 134, as shown in FIG. 23. Alternatively, the top surface of the protruding portion PRO may be a convex surface. In this case, the portion ‘A’ of the semiconductor device may be fabricated to have the structure of FIG. 8. A height of the protruding portion PRO may be about or exactly 10% to about or exactly 50% of the thickness of the pad 130.

The third mask pattern MP3 may be removed. As a result of the removal of the third mask pattern MP3, the top surface of the seed layer 135 under the third mask pattern MP3 may be exposed to the outside.

The process described with reference to FIGS. 18 and 19 may be performed. For example, the seed layer 135 may be patterned. For example, an etching process using the pad 130 as an etch mask may be performed on a portion of the seed layer 135 exposed at a side of the pad 130. As a result of the etching process, the seed layer 135 may be left between the pad 130 and the protection layer 120.

Thereafter, referring to FIGS. 1 and 2, the solder resist layer 140 may be formed on the protection layer 120. The solder resist layer 140 may be provided to enclose the pad 130. The solder resist layer 140 may be horizontally spaced apart from the pad 130.

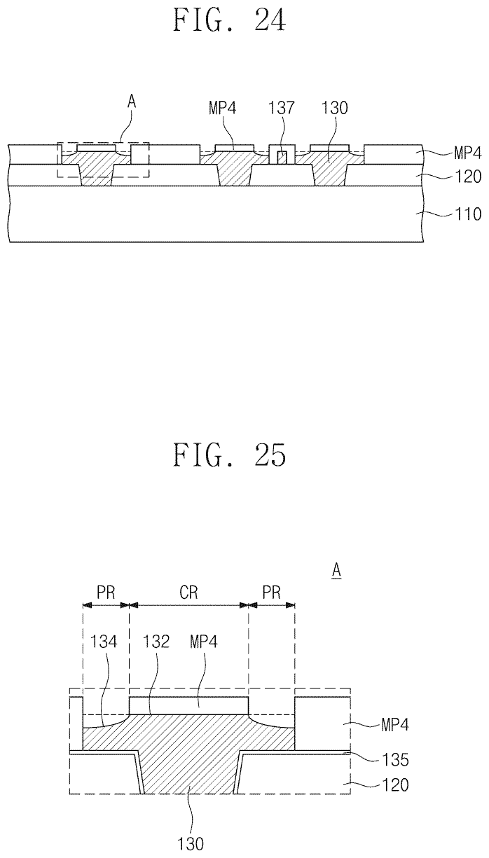

FIGS. 24 and 25 are diagrams illustrating a method of fabricating a semiconductor device, according to some example embodiments of the inventive concepts. FIG. 24 is a sectional view illustrating the semiconductor device, and FIG. 25 is an enlarged sectional view illustrating a portion ‘A’ of FIG. 24.

Referring to FIGS. 24 and 25, a fourth mask pattern MP4 may be formed on the resulting structure of FIGS. 18 and 19. The fourth mask pattern MP4 may have a pattern hole, which is formed to vertically penetrate the fourth mask pattern MP4 and to expose the peripheral portion 134 of the top surface of the pad 130. The fourth mask pattern MP4 may cover the center portion 132 of the top surface of the pad 130. The fourth mask pattern MP4 may have a circular, tetragonal, polygonal, cross, asterisk, or stellate shape, when viewed in a plan view.

The peripheral portion 134 of the top surface of the pad 130 may be etched. For example, the etching process may be performed using the fourth mask pattern MP4 as an etch mask. As a result, the peripheral portion 134 of the pad 130 may be locally etched. During the etching process, the center portion 132 of the pad 130 may not be etched by the fourth mask pattern MP4. As a result of the etching process, the peripheral portion 134 may be located at a vertical level that is lower than a vertical level of the center portion 132. That is, the peripheral portion 134 may be a concave surface that is recessed from the center portion 132. A vertical level difference between the center and peripheral portions 132 and 134 may be about or exactly 10% to about or exactly 50% of the thickness of the pad 130.

In a semiconductor device according to some example embodiments of the inventive concepts, a pad of a substrate may have a recessed portion, which is formed in a center portion of a top surface thereof. Thus, when an additional device is mounted on the pad, a connection terminal may be easily aligned to the pad. In more detail, the additional device may be moved to the substrate such that the connection terminal is placed adjacent to the pad. Here, the additional device may be slid to align the connection terminal to the pad. This is because the recessed portion, which is concavely recessed toward an inner portion of the pad, is formed in the pad. That is, the substrate and the additional device may be aligned to each other in a self-aligned manner (e.g., without any additional alignment component). As a result, the additional device may be mounted on the substrate without any misalignment issue, and the connection terminal of the additional device may be stably bonded to the pad. Consequently, it may be possible to reduce or suppress a non-wet failure in a semiconductor device.

Furthermore, the pad of the substrate of the semiconductor device may have a recessed portion, which is formed in the center portion of the top surface thereof. In some example embodiments, there may be corners between center and peripheral portions of the pad. Accordingly, in a process of mounting the additional device on the pad, the additional device may be aligned to the substrate in a self-aligned manner (e.g., without an additional alignment component) by a surface tension of a solder ball melted during a reflow step. In the case where the center portion has a polygonal or asterisk shape in a plan view, the number of the corners between the center and peripheral portions may be increased, and this may facilitate the self-alignment process using the surface tension of the melted solder ball.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

While example embodiments of the inventive concepts have been particularly shown and described, it will be understood by one of ordinary skill in the art that variations in form and detail may be made therein without departing from the spirit and scope of the attached claims.

1. A semiconductor device, comprising:
a substrate;
a pad on the substrate and connected to an interconnection pattern in the substrate; and
a solder resist layer on the substrate, the solder resist layer having an opening exposing the pad,
a top surface of the pad including
a center region; and
a peripheral region surrounding the center region,
the center region of the top surface of the pad at a level different from the peripheral region of the top surface of the pad, and
a first width of the pad being constant regardless of a distance from the substrate.

2. The semiconductor device of claim 1, wherein
the center region of the top surface of the pad is at a level lower than the peripheral region of the top surface of the pad, and
the center region comprises a concave surface that is recessed from the peripheral region.

3. The semiconductor device of claim 1, wherein
the center region of the top surface of the pad is at a level higher than the peripheral region of the top surface of the pad, and
the center region comprises a convex surface protruding from the peripheral region.

4. The semiconductor device of claim 1, wherein the center region comprises a flat surface that is stepped with the peripheral region.

5. The semiconductor device of claim 1, wherein the center region has a circular, tetragonal, polygonal, or cross shape, when viewed in a plan view.

6. The semiconductor device of claim 1, wherein a level difference between the center and peripheral region is 10% to 50% of a thickness of the pad.

7. The semiconductor device of claim 6, wherein the level difference between the center and peripheral region ranges from 3 μm to 10 μm.

8. The semiconductor device of claim 1, wherein a width of the center region is 30% to 70% of a width of the pad.

9. The semiconductor device of claim 8, wherein the width of the center region ranges from 30 μm to 50 μm.

10. The semiconductor device of claim 1, wherein the solder resist layer is spaced apart from the pad.

11. The semiconductor device of claim 1, further comprising:
a semiconductor chip having a bottom surface, on which a chip pad is provided; and
a solder portion between the chip pad and the pad to directly connect the chip pad to the pad,
wherein the solder portion is in contact with an entirety of the center region.

12. A semiconductor device, comprising:
a substrate having a top surface, on which a substrate pad is provided;
a semiconductor chip on the substrate, the semiconductor chip having a bottom surface, on which a chip pad is provided; and
a solder portion between the substrate pad and the chip pad to directly connect the chip pad to the substrate pad,
a top surface of the substrate pad facing the chip pad comprising
a first point on a center portion of the substrate pad; and
a second point adjacent to an edge of the substrate pad,
a difference in vertical level between the first and second points being 10% to 50% of a thickness of the substrate pad.

13. The semiconductor device of claim 12, wherein
the top surface of the substrate pad comprises a protruding portion, protruding toward the chip pad,
the first point is placed on the protruding portion, and
the second point is placed between the protruding portion and an outer side surface of the substrate pad.

14. The semiconductor device of claim 13, wherein a top surface of the protruding portion has a convex surface or has a flat surface.

15. The semiconductor device of claim 12, wherein
the top surface of the substrate pad has a recessed portion, recessed toward an inside of the substrate pad,
the first point is on the recessed portion, and
the second point is between the recessed portion and an outer side surface of the substrate pad.

16. The semiconductor device of claim 15, wherein a top surface of the recessed portion has a concave surface or flat surface.

17. The semiconductor device of claim 12, wherein
the top surface of the substrate pad has a center region and a peripheral region, located at different vertical levels from each other,
the first point is on the center region,
the second point is on the peripheral region, and
a width of the center region is 30% to 70% of a width of the substrate pad.

18. The semiconductor device of claim 17, wherein the center region has a circular, tetragonal, polygonal, or cross shape, when viewed in a plan view.

19. The semiconductor device of claim 12, wherein a width of the substrate pad is constant, regardless of a vertical level.

20. (canceled)

21. A semiconductor device, comprising:
a substrate, the substrate comprising a substrate pad, on a top surface of the substrate, and a solder resist layer, on the top surface of the substrate and surrounding the substrate pad;
a semiconductor chip, on the substrate and having a chip pad on a bottom surface thereof; and
a solder portion, between the substrate pad and the chip pad and directly connecting the chip pad to the substrate pad,
a top surface of the substrate pad facing the chip pad comprising
a curved surface; and
a flat surface surrounding the curved surface,
the solder resist layer being spaced apart from the substrate pad.

22.-33. (canceled)
